(19) United States
(12) Patent Application Publication
(10) Pub. No.: US 2008/0156523 A1
(43) Pub. Date: Jul. 3, 2008

(54) PRINTED-WIRING BOARD

(75) Inventor: Shinichiro SAITO, Yokosuka-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/964,525

(22) Filed: Dec. 26, 2007

(30) Foreign Application Priority Data
Dec. 27, 2006 (JP) 2006-351586

(51) Int. Cl. H05K 1/11; H01R 12/04

(52) U.S. Cl. 174/265

(57) ABSTRACT

A printed-wiring board includes: a board made of insulator; a wiring pattern to transfer an electric signal which is made of patterned metallic conductor and formed on at least one of a main surface and a rear surface of the board; and an electric power layer formed on the rear surface of the board and/or in the board. The electric power layer includes a mechanism to increase and decrease a capacitance and an inductance thereof.

### CROSS-REFERENCE TO RELATED APPLICATIONS

This application is based upon and claims the benefit of priority from the prior Japanese Patent Application No. 2006-351586, filed on Dec. 27, 2006; the entire contents of which are incorporated herein by reference.

### BACKGROUND OF THE INVENTION

1. Field of the Invention

The present invention relates to a printed-wiring board particularly requiring high speed operation, high density package and multilayered package.

2. Description of the Related Art

A high density packaged and multilayered printed wiring board, on which (an) IC chip(s) with high speed operationality is(are) mounted, is available for various electronic devices such as a computer. With a conventional printed-wiring board, a high frequency signal is transferred under a transfer mode using a micro strip line, a strip line or a coplanar waveguide. In this case, the ground layer (ground plane) or the power source layer (power source plane) of the conventional printed-wiring board is formed of a metallic conductor in a plane shape. In this case, the characteristic impedance of the ground plane can be represented by the following equation:

$${Z}_{0} = \sqrt{\frac{R + j ω L}{G + j ω C}} \qquad ( 1 )$$

### Inherently, the characteristic impedance of the ground plane becomes almost zero so that no difference in potential is generated on the ground plane.

However, the characteristic impedance, which is inherently zero as described above, is generated in the ground plane originated from the high speed of the IC operation and the high speed of signals to be transferred (the increase of the angular frequency ω in the equation (1)) so that the difference in potential may be momentarily generated on the ground plane. Moreover, the ground (electrode) plane is segmentalized originated from the high density package so that the DC resistance of the ground (electrode) plane (represented by “R” in the equation (1)) is increased and the capacitance of the ground (electrode) plane (represented by “C” in the equation (1) is decreased, and the inductance of the ground (electrode) plane (represented by “L” in the equation (1)) is increased, thereby increasing the characteristic impedance of the ground (electrode) plane. In this point of view, the ground (electrode) plane is unlikely to function as a reference potential for a high frequency signal. Under these circumstances, the resonance phenomenon is generated on the ground (electrode) plane originated from the ordinary wave (stationary wave), thereby causing various disadvantages.

For example, the ICs may malfunction so that the corresponding switching noises may increase originated from the resonance phenomenon. In this case, the switching noises are superimposed with the signals to be transferred, thereby causing some problems such as the increase of unnecessary electromagnetic radiation and the deterioration of transmission characteristic performance, reflecting property and crosstalk characteristic.

Conventionally, the resonance phenomenon can be suppressed by providing condenser parts called as “bypass capacitor”s. However, the packaging areas of parts such as ICs are reduced as the number of the bypass capacitors is increased, thereby disturbing the downsize of the intended electronic device. Moreover, the signals to be transferred are digital signals which are composed of various superimposed frequency components and ranged over the corresponding various frequencies. In this case, in order to suppress the resonance phenomenon, a plurality of bypass capacitors with the respective different capacitances are required. Moreover, the bypass capacitors may not function as condensers within a high frequency range.

Reference 1 teaches that the ground electrode of the printed-wiring board is formed in mesh-like shape, not plane shape so as to impart the high speed transfer property to the printed-wiring board. Even though the mesh-shaped ground electrode is employed, the characteristic impedance of the ground electrode can not be suppressed sufficiently over the wide ranged high frequency digital signals when the high frequency digital signals are transferred.

[Reference 1] JP-A 7-321463 (KOKAI)

### BRIEF SUMMARY OF THE INVENTION

It is an object of the present invention, in view of the above-described problems, to provide a printed-wiring board which can maintain the characteristic impedance of the ground (electrode) plane almost zero, thereby suppressing the resonance phenomenon of the ground (electrode) plane and thus, realizing the excellent transmission characteristics over the wide frequency range and the reduction of unnecessary electromagnetic radiation.

In order to achieve the above object, an aspect of the present invention relates to a printed-wiring board, including: a board made of insulator; a wiring pattern to transfer an electric signal which is made of patterned metallic conductor and formed on at least one of a main surface and a rear surface of the board; and an electric power layer formed on the rear surface of the board and/or in the board; wherein the electric power layer includes a mechanism to increase and decrease a capacitance and an inductance thereof.

According to the aspect of the present invention, the electric power layer of the printed-wiring board includes the mechanism to increase and decrease the capacitance and the inductance thereof. Therefore, the characteristic impedance of the electric power layer can be sufficiently suppressed against the signals to be transferred with wide range frequency, and thus, the resonance phenomenon in the electric power layer can be sufficiently suppressed.

In an embodiment, the electric power layer includes a plate-like uniform electric power layer and a lattice-like electric power layer which are stacked one another and electrically connected with one another. The lattice-like electric power layer can be formed by performing half-etching for a metallic plate so as to form a pattern at the metallic plate. In this case, the pattern of the metallic plate constitutes the lattice-like electric power layer and the main body of the metallic plate constitutes the plate-like uniform electric power layer. In this case, some capacitances are generated between the adjacent lattices in the lattice-like electric power layer so as to increase the total capacitance of the electric power layer. Since the lattice-like electric power layer is electrically connected with the plate-like electric power layer, the increase of the inductance of the electric power layer can be suppressed over high frequency range.

The DC components of signals to be transferred such as digital signals are transferred in the plate-like electric power layer and the high frequency components of the signals to be transferred are transferred in the superficial skins of the lattice-like electric power layers. Therefore, the increase of the characteristic impedance of the electric power layer due to the increase in resistance for the signals to be transferred can be suppressed. As a result, in the embodiment where the electric power layer includes the plate-like uniform electric power layer and the lattice-like electric power layer which are stacked one another and electrically connected with one another, the characteristic impedance of the electric power layer can be sufficiently suppressed against the signals to be transferred with wide range frequency, and thus, the resonance phenomenon in the electric power layer can be sufficiently suppressed.

Suppose that the height of the electric power layer is defined as “h” and the area of the plate-like electric power layer is defined as “S”, the height of the surface convex-concave portion of the lattice-like electric power layer is set within a range of 0.2 h to 0.8 h, and the ratio of the exposed area of the plate-like electric power via the lattice-like electric power layer is set within a range of 0.4 S to 0.9 S.

In another embodiment, the electric power layer is configured such that a plurality of holes are formed at a plate-like uniform electric power layer so as not to penetrate through the plate-like uniform electric power layer. In this case, some capacitances are generated between the adjacent holes in the electric power layer so as to increase the total capacitance of the electric power layer. Moreover, the increase of the inductance of the electric power layer over high frequency range can be suppressed by the surface convex-concave portion of the holes.

Then, since the electric power layer contains the areas without the holes, the DC components of the signals to be transferred such as digital signals are transferred in the electric power layer not subject to the holes. Therefore, the increase of the characteristic impedance of the electric power layer due to the increase in resistance for the signals to be transferred can be suppressed. As a result, the characteristic impedance of the electric power layer can be sufficiently suppressed against the signals to be transferred with wide range frequency, and thus, the resonance phenomenon in the electric power layer can be sufficiently suppressed.

The printed-wiring board can be formed various configurations. For example, the wiring pattern can be configured as a micro strip line (MSL) on the main surface of the board. Then, the wiring pattern can be configured as a strip line (SL) in the board. Then, a pair of ground electrodes is formed so as to sandwich the metallic conductor along the long direction of the metallic conductor with parallel to the metallic conductor so that the metallic conductor and the wiring pattern constitute a coplanar waveguide (CPW).

Particularly not exemplified, the printed-wiring board as described above according to the aspects of the present invention can be applied for various microwave circuit boards which can be considered by the person skilled in the art.

According to the aspect of the present invention can be provided a printed-wiring board which can maintain the characteristic impedance of the ground (electrode) plane almost zero, thereby suppressing the resonance phenomenon of the ground (electrode) plane and thus, realizing the excellent transmission characteristics over the wide frequency range and the reduction of unnecessary electromagnetic radiation.

### BRIEF DESCRIPTION OF THE SEVERAL VIEWS OF THE DRAWINGS

FIG. 1 is a perspective view illustrating an embodiment of the printed-wiring board according to the present invention.

FIG. 2 is a perspective view illustrating the structure of the electric power layer of the printed-wiring board in FIG. 1.

FIG. 3 is a cross sectional view of the electric power layer as viewed from the side thereof.

FIG. 4 is a perspective view of a modified embodiment of the printed-wiring board according to the present invention.

FIG. 5 is a perspective view illustrating another embodiment of the printed-wiring board according to the present invention.

FIG. 6 is a perspective view illustrating still another embodiment of the printed-wiring board according to the present invention.

### DETAILED DESCRIPTION OF THE INVENTION

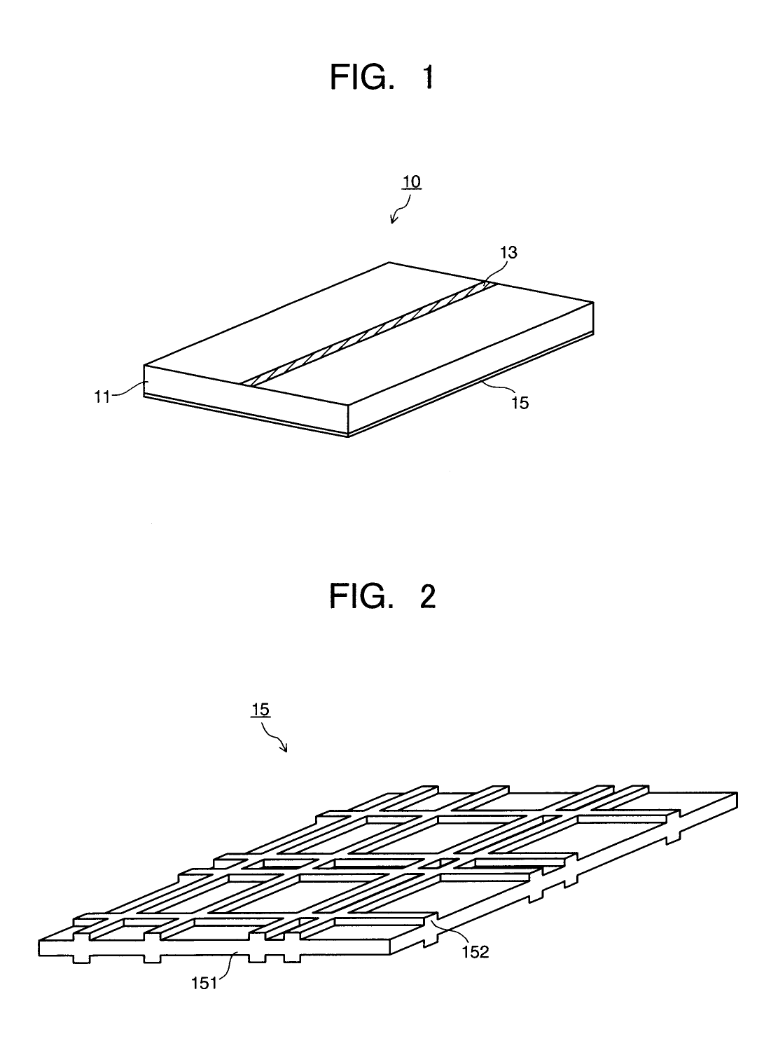

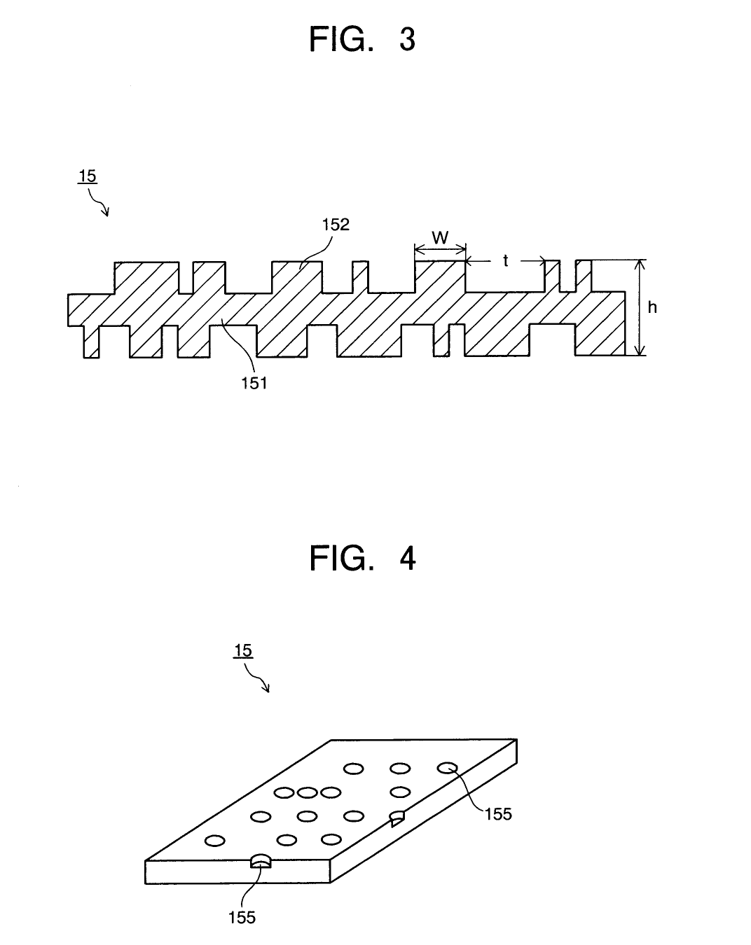

Hereinafter, the present invention will be described in detail with reference to the drawings. FIG. 1 is a perspective view illustrating an embodiment of the printed-wiring board according to the present invention. FIG. 2 is a perspective view illustrating the structure of the electric power layer of the printed-wiring board in FIG. 1. FIG. 3 is a cross sectional view of the electric power layer as viewed from the side thereof.

The printed-wiring board 10 illustrated in FIG. 1 includes a board 11 made of insulator, a metallic conductor (wiring pattern) 13 to transfer (a) microwave electric signal(s) which is formed on the main surface of the board 11 and an electric power layer 15 formed on the rear surface of the board 11. The electric power layer 15 functions as a reference electrode for the metallic conductor 13 and is maintained constant electric potential for the metallic conductor 13 so that the microwave electric signal(s) can be transferred under good condition. The electric power layer 15 may be electrically grounded, but may be maintained a predetermined electric potential only if the microwave electric signal(s) can be transferred in the metallic conductor 13.

In this embodiment, the metallic conductor 13 (wiring pattern) is formed in micro strip line (MSL).

Then, as illustrated in FIGS. 2 and 3, the electric power layer 15 is composed of a plate-like uniform electric power layer 151 and a lattice-like electric power layer 152 which are stacked one another. The plate-like electric power layer 151 is electrically connected with the lattice-like electric power layer 152. In this embodiment, a pair of lattice-like electric power layers 152 is prepared so as to sandwich the plate-like electric power layer 151. In other words, the lattice-like electric power layers 152 are formed on the main surface and the rear surface of the plate-like electric power layer 151, respectively.

In this embodiment, some capacitances are generated between the adjacent lattices in the lattice-like electric power layers 152 so as to increase the total capacitance of the electric power layer 15. Since the lattice-like electric power layers 152 are electrically connected with the plate-like electric power layer 151, the increase of the inductance of the electric power layer 15 can be suppressed over high frequency range. The DC components of the signals to be transferred such as digital signals are transferred in the plate-like electric power layer 151 and the high frequency components of the signals to be transferred are transferred in the superficial skins of the lattice-like electric power layers 152. Therefore, the increase of the characteristic impedance of the electric power layer 15 due to the increase in resistance for the signals to be transferred can be suppressed.

As a result, the characteristic impedance of the electric power layer 15 can be sufficiently suppressed against the signals to be transferred with wide range frequency, and thus, the resonance phenomenon in the electric power layer 15 can be sufficiently suppressed. Accordingly, the printed-wiring board 10 can have the excellent transmission characteristic over wide range frequency and reduce the unnecessary electromagnetic radiation.

In this embodiment, suppose that the height of the electric power layer 15 is defined as “h”, and the area of the plate-like electric power layer 15 is defined as “S”, the height of the surface convex-concave portion of the lattice-like electric power layer 152 may be set within a range of 0.2 h to 0.8 h, and the ratio of the exposed area of the plate-like electric power 151 via the lattice-like electric power layer 152 may be set within a range of 0.4 S to 0.9 S. In this case, the increase of the characteristic impedance of the electric power layer 151 can be suppressed effectively. Herein, the phrase of “the ratio of the exposed area of the plate-like electric power 151 via the lattice-like electric power layer 152” means the summation of the areas represented by the reference character “t”.

The board 11 may be made of a given insulator. As the insulator can be exemplified paper (e.g., FR-1, FR-2, XXXpc, Xpc, FR-3), glass (e.g., FR-4, G-10, FR-5, G-11, GPY), epoxy or polyester based composite (CEM-1, CEM-3, FR-6), polyester, polyimide or glass epoxy based flexible material, polysulfone, polyetherimide or polyether thermoplastic resin, alumina, alumina nitride or silicon carbide low temperature sintered ceramic material and liquid crystal.

The metallic conductor 13 and the electric power layer 15 may be made of e.g., Cu, Ag, Au, aluminum or an alloy thereof.

The printed-wiring board 10 may be made as a rigid board or a flexible board entirely.

FIG. 4 is a perspective view of a modified embodiment of the printed-wiring board according to the present invention. Concretely, the printed-wiring board in this embodiment is formed in the same manner as the printed-wiring board in the embodiment relating to FIGS. 1 to 3 except the structure of the electric power layer. Like or corresponding components are designated by the same reference characters throughout the drawings.

In the embodiment relating to FIGS. 1 to 3, the electric power layer 15 is composed of the plate-like electric power layer 151 and the lattice-like electric power layers 152. In this embodiment relating to FIG. 4, the electric power layer 15 is formed in plate so that a plurality of holes 155 not penetrating through the layer 15 are formed at the layer 15. In this case, some capacitances are generated between the adjacent holes 155 in the electric power layer 15 so as to increase the total capacitance of the electric power layer 15. Moreover, since the electric power layer with the holes 155 are electrically connected with the plate electric power layer substantially, the increase of the inductance in the electric power layer can be suppressed over high frequency range.

Furthermore, since the electric power layer 15 contains the areas without the holes 155, the DC components of the signals to be transferred such as digital signals are transferred in the electric power layer 15 not subject to the holes 155. Therefore, the increase of the characteristic impedance of the electric power layer 15 due to the increase in resistance for the signals to be transferred can be suppressed. As a result, the characteristic impedance of the electric power layer 15 can be sufficiently suppressed against the signals to be transferred with wide range frequency, and thus, the resonance phenomenon in the electric power layer 15 can be sufficiently suppressed. Accordingly, the printed-wiring board 10 can have the excellent transmission characteristic over wide range frequency and reduce the unnecessary electromagnetic radiation.

Other requirements such as the constituent materials of the board and metallic conductor in this embodiment can be determined in the same manner as the embodiment relating to FIGS. 1 to 3.

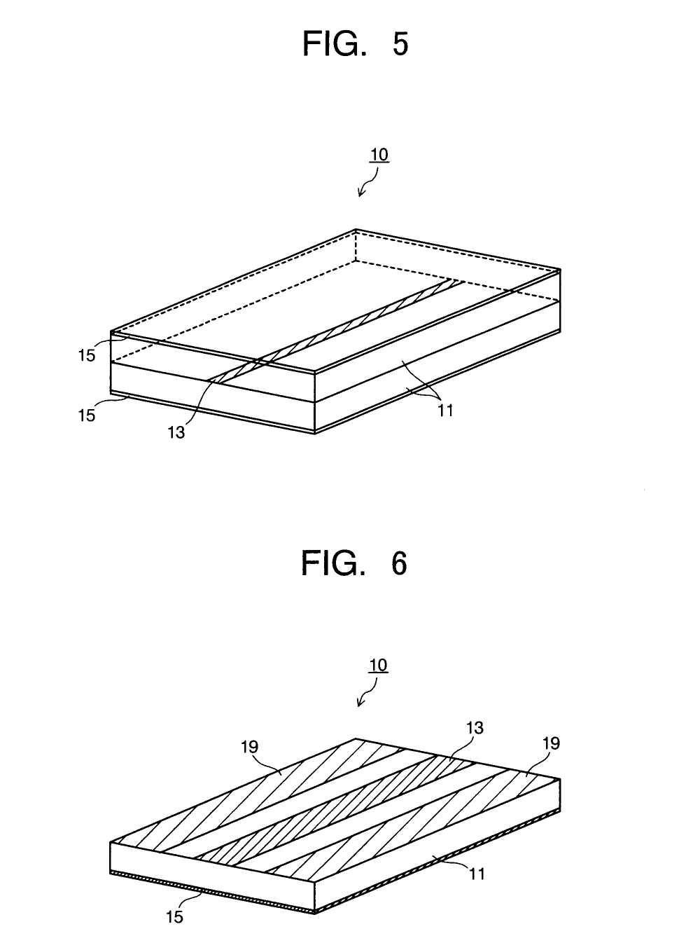

FIG. 5 is a perspective view illustrating another embodiment of the printed-wiring board according to the present invention. Like or corresponding components are designated by the same reference characters throughout the drawings.

The printed-wiring board 10 illustrated in FIG. 5 includes aboard 11 made of insulator, a metallic conductor (wiring pattern) 13 to transfer (a) microwave electric signal(s) which is elongated parallel to the main surface and the rear surface of the board 11 and electric power layers 15 formed on the main surface and the rear surface of the board 11. The electric power layer 15 functions as a reference electrode for the metallic conductor 13 and is maintained constant electric potential for the metallic conductor 13 so that the microwave electric signal(s) can be transferred under good condition. The electric power layer 15 may be electrically grounded, but may be maintained a predetermined electric potential only if the microwave electric signal(s) can be transferred in the metallic conductor 13.

In this embodiment, the metallic conductor 13 (wiring pattern) is formed in strip line (SL). Then, not shown clearly, the electric power layer 15 may be composed of a plate-like uniform electric power layer 151 and a lattice-like electric power layer 152 in the same manner as the embodiment relating to FIGS. 1 to 3 or may include holes 155 not penetrating through the layer 15 in the same manner as the embodiment relating to FIG. 4. In any case, the electric power layers composing the electric power layer 15 are electrically connected with one another. Therefore, the increase of the characteristic impedance of the electric power layer 15 due to the increase in resistance for the signals to be transferred can be suppressed. As a result, the characteristic impedance of the electric power layer 15 can be sufficiently suppressed against the signals to be transferred with wide range frequency, and thus, the resonance phenomenon in the electric power layer 15 can be sufficiently suppressed. Accordingly, the printed-wiring board 10 can have the excellent transmission characteristic over wide range frequency and reduce the unnecessary electromagnetic radiation.

Other requirements such as the constituent materials of the board and metallic conductor in this embodiment can be determined in the same manner as the embodiment relating to FIGS. 1 to 3.

FIG. 6 is a perspective view illustrating still another embodiment of the printed-wiring board according to the present invention. Like or corresponding components are designated by the same reference characters throughout the drawings.

The printed-wiring board 10 illustrated in FIG. 6 includes a board 11 made of insulator, a metallic conductor (wiring pattern) 13 to transfer (a) microwave electric signal(s) which is formed on the main surface the board 11 and an electric power layer 15 formed on the rear surface of the board 11. The electric power layer 15 functions as a reference electrode for the metallic conductor 13 and is maintained constant electric potential for the metallic conductor 13 so that the microwave electric signal(s) can be transferred under good condition. The electric power layer 15 may be electrically grounded, but may be maintained a predetermined electric potential only if the microwave electric signal(s) can be transferred in the metallic conductor 13.

In this embodiment, a pair of ground electrode layers 19 are formed in both sides of the metallic conductor 13 so as to sandwich the metallic conductor 13. The metallic conductor 13 and the ground electrode layers 19 constitute the coplanar waveguide (CPW) wiring pattern.

Not shown clearly, the electric power layer 15 may be composed of a plate-like uniform electric power layer 151 and a lattice-like electric power layer 152 in the same manner as the embodiment relating to FIGS. 1 to 3 or may include holes 155 not penetrating through the layer 15 in the same manner as the embodiment relating to FIG. 4. In any case, the electric power layers composing the electric power layer 15 are electrically connected with one another. Therefore, the increase of the characteristic impedance of the electric power layer 15 due to the increase in resistance for the signals to be transferred can be suppressed. As a result, the characteristic impedance of the electric power layer 15 can be sufficiently suppressed against the signals to be transferred with wide range frequency, and thus, the resonance phenomenon in the electric power layer 15 can be sufficiently suppressed. Accordingly, the printed-wiring board 10 can have the excellent transmission characteristic over wide range frequency and reduce the unnecessary electromagnetic radiation.

Other requirements such as the constituent materials of the board and metallic conductor in this embodiment can be determined in the same manner as the embodiment relating to FIGS. 1 to 3.

Although the present invention was described in detail with reference to the above examples, this invention is not limited to the above disclosure and every kind of variation and modification may be made without departing from the scope of the present invention.

What is claimed is:

1. A printed-wiring board, comprising:
a board made of insulator;
a wiring pattern to transfer an electric signal which is made of patterned metallic conductor and formed on at least one of a main surface and a rear surface of said board; and
an electric power layer formed on said rear surface of said board and/or in said board,
wherein said electric power layer includes a mechanism to increase and decrease a capacitance and an inductance thereof.

2. The printed-wiring board as set forth in claim 1,
wherein said electric power layer includes a plate-like uniform electric power layer and a lattice-like electric power layer which are stacked one another and electrically connected with one another.

3. The printed-wiring board as set forth in claim 2,
wherein suppose that a height of said electric power layer is defined as “h” and an area of said plate-like electric power layer is defined as “S”, a height of a surface convex-concave portion of said lattice-like electric power layer is set within a range of 0.2 h to 0.8 h, and a ratio of an exposed area of said plate-like electric power via said lattice-like electric power layer is set within a range of 0.4 S to 0.9 S.

4. The printed-wiring board as set forth in claim 2,
wherein a DC component of a signal to be transferred is transferred in said plate-like uniform electric power layer and a high frequency component of said signal is transferred on a superficial skin of said lattice-like electric power layer.

5. The printed-wiring board as set forth in claim 1,
wherein said electric power layer is configured such that a plurality of holes are formed at a plate-like uniform electric power layer so as not to penetrate through said plate-like uniform electric power layer.

6. The printed-wiring board as set forth in claim 5,
wherein a DC component of a signal to be transferred is transferred in an area of said plate-like uniform electric power layer without said holes.

7. The printed-wiring board as set forth in claim 1,
wherein said electric power layer is made of Cu or plating material.

8. The printed-wiring board as set forth in claim 1,
wherein said board is made of polyimide based resin.

9. The printed-wiring board as set forth in claim 1,
wherein said wiring pattern constitutes a micro strip line (MSL) on said main surface of said board.

10. The printed-wiring board as set forth in claim 1,
wherein said wiring pattern constitutes a strip line (SL) on said main surface of said board.

11. The printed-wiring board as set forth in claim 1, further comprising a pair of ground electrodes formed so as to sandwich said metallic conductor along a long direction of said metallic conductor with parallel to said metallic conductor so that said metallic conductor and said wiring pattern constitute a coplanar waveguide (CPW).

12. A multilayer printed wiring board comprising a plurality of printed wiring boards, each printed-wiring board being one unit, as set forth in claim 1.
